(19) United States
(12) Patent Application Publication
(10) Pub. No.: US 2010/0038619 A1
(43) Pub. Date: Feb. 18, 2010

(54) VARIABLE RESISTANCE ELEMENT, MANUFACTURING METHOD THEREOF, AND ELECTRONIC DEVICE

(76) Inventors: Ayuka Tada, Toyota (JP); Kimihiko Ito, Tokyo (JP)

Correspondence Address: Mr. Jackson Chen, 6535 N. STATE HWY 161, IRVING, TX, 75039, US

(21) Appl. No.: 12/532,666

(22) PCT Filed: Mar. 14, 2008
(86) PCT No.: PCT/JP2008/054739

§ 371 Date: Sep. 23, 2009

(30) Foreign Application Priority Data
Mar. 28, 2007 (JP) 2007-084569

(51) Int. Cl. H01L 45/00; H01L 21/02; H01C 7/10

(52) U.S. Cl. 257/3; 438/382; 338/20; 257/E45.002; 257/E21.006

(57) ABSTRACT

A variable resistance element includes a first conductive portion; an insulating film pattern provided on the first conductive portion; a level difference with respect to the upper surface of the first conductive portion, the level difference being formed of the insulating film pattern; a variable resistance film provided on a side surface of the level difference and having contact with the upper surface of the first conductive portion on the lower-end side of the side surface of the level difference; and a second conductive portion having contact with the variable resistance film on the upper-end side of the side surface of the level difference.

### TECHNICAL FIELD

The present invention relates to a structure of a variable resistance element and a manufacturing method thereof. More particularly, the invention relates to a switching element and a memory element which take advantage of creating a low-resistance state and a high-resistance state by, for example, applying a pulse between a lower electrode and an upper electrode, and relates to electronic devices such as a rewritable logic circuit and a memory which utilize the elements.

### BACKGROUND ART

In related semiconductor integrated circuits, a chip is generally remanufactured when a design change is made, thus causing the circuits to be extremely costly. Particular in the case of an ultra very large-scale integrated circuit using the most-advanced technique, the cost of masks necessary for manufacturing has become enormous along with the advance of miniaturization. Accordingly, there has been a growing demand for a technique to realize a required change in circuit configuration in some applications, without remaking masks or remanufacturing chips.

As a well-known example, there can be mentioned an FPGA (Field Programmable Gate Array). There are several methods used to change circuit configurations. One of the most often-used methods is to change circuit configurations using a switch which combines a unit of a semiconductor memory element (SRAM) and an element called a pass transistor. With this technique, users can freely change circuit configurations. However, since a single switch is composed of a multitude of semiconductor transistors, the occupation area of the switch is large. Thus, the ratio of the areas of a logic circuit and an arithmetic circuit to a chip area lowers. In addition, the technique has the problem that manufacturing costs increase. Furthermore, since the electrical resistance of the switch in an on state is higher than wiring resistance, the transmission delay of signals becomes a problem in some cases.

As a switch for circuit configuration often used to attain high-speed operation, there is an element called an anti-fuse. By taking advantage of the dielectric breakdown or the like of a material constituting an element, it is possible to place in an on state only the locations where wire-to-wire interconnection is required. However, a change in circuit configuration can only be made once, though the occupation area can be made smaller than that of the above-described switch using semiconductor transistors.

A study of a nonvolatile variable resistance element, which is similar in structure and operation to the anti-fuse but the resistive state of which can be switched a plurality of times, has become active with a focus on application to nonvolatile memories. For example, there can be mentioned a PRAM (Phase-change RAM) technology which takes advantage of a change in the crystalline phase of a chalcogenide semiconductor. In addition, efforts have been made to develop a technique capable of attaining resistance change over several orders of magnitude at room temperature by providing a voltage pulse to an MIM-type element in which mainly an oxide of transition metal is sandwiched between upper and lower electrodes.

One of the issues in applying such a novel variable resistance element technology to a switch for circuit reconfiguration or a nonvolatile memory is the miniaturization of elements in order to realize high integration. Specifically, the issue is the realization of a technique to reduce the area of a variable resistance element as much as possible.

In connection with such a variable resistance element technology, the below-described studies have been made.

The technique described in patent document 1 (Japanese Patent Laid-Open No. 2004-241396) uses such a structure of a variable resistance element as illustrated in FIG. 13. In the figure, reference numeral 101 denotes a lower electrode, reference numeral 102 denotes a variable resistance film, reference numeral 103 denotes an upper electrode, and reference numeral 100 denotes a substrate. In this case, the area of the variable resistance element is determined by the area of the upper electrode. However, it is not possible to set the area of the upper electrode to the minimum exposure dimension. In order to form a via for ensuring interconnection to the upper electrode, the size of the upper electrode needs to be made larger than the minimum dimension of lithography technology. Furthermore, in this technique, greater exactness is required for alignment in a lithography step with a decrease in the area of an element, thus making manufacturing difficult. Still furthermore, the technique has the problem that the variable resistance film suffers etching damage at the time of etching the upper electrode.

The techniques described in patent document 2 (Japanese Patent Laid-Open No. 2004-241535) and patent document 3 (Japanese Patent Laid-Open No. 2005-197634) use such variable resistance element structures as illustrated in FIGS. 14 and 15, respectively. In the figures, reference numeral 101 denotes a lower electrode, reference numeral 102 denotes a variable resistance film, reference numeral 103 denotes an upper electrode, reference numeral 100 denotes a substrate, and reference numeral 110 denotes an interlayer insulating film. In this case, the area of the variable resistance element can be determined by the minimum dimension of lithography technology. In the case of the structure illustrated in FIG. 14, however, it becomes increasingly difficult to bury the variable resistance film and the upper electrode in the via with a decrease in the area of an element. It also becomes difficult to ensure the reliability of interconnects. In the case of the structure illustrated in FIG. 15, the variable resistance film is exposed to the ambient atmosphere of treatments in a step of via formation, such as etching and is, therefore, susceptible to process damage.

The technique described in non-patent document 1 (D. C. Kim et al., “Electrical observations of filamentary conductions for the resistive memory switching in NiO films,” Applied Physics Letter, Vol. 88, 202102, 2006) uses NiO as a variable resistance film.

Problems in realizing such variable resistance elements as described above will be summarized below.

(1) In cases where a transition metal oxide-based variable resistance film, such as NiO, is used as a variable resistance film, electrical resistance in a low-resistance state has a small degree of dependence on an element area. In contrast, an electrical resistance value in a high-resistance state often exhibits a tendency to increase with a decrease in the element area. Consequently, by reducing as much as possible an effective element area, such as the cross-sectional area of the variable resistance film, it is possible to increase the ratio of electrical resistance between the low-resistance state and the high-resistance state. However, a conventionally-used variable resistance element structure has the problem that element dimensions depend on the minimum processing dimension of lithography.

(2) In cases where either an upper electrode or a variable resistance film or both are microfabricated using a dry etching technique in the formation of the variable resistance element, e.g., such a structure as illustrated in FIG. 13 is formed, the peripheral part of the variable resistance film (processed-side surface thereof when the variable resistance film is processed) of an element is exposed to an etching gas. Accordingly, the influence of this exposure becomes greater for elements having smaller areas, thus causing element characteristics to degrade.

(3) In cases where a variable resistance film is deposited inside a via hole and the variable resistance film formed in the bottom of the via hole is used as a component of a variable resistance element, as in the structure illustrated in FIG. 14, a via hole having a small opening area must be formed in an insulating film on a lower electrode, and the variable resistance film and the upper electrode must be buried in the via hole. However, this process becomes more difficult for elements having smaller areas. This difficulty, for example, leads to a reduction in the film thickness of the variable resistance film in the bottom corners of the via hole, thus making uniform film formation difficult to achieve. Consequently, element performance degrades or the variation of element performance becomes large.

(4) In cases where a via hole is formed on a variable resistance film, as in the structure illustrated in FIG. 15, the variable resistance film deteriorates due to dry etching, resist separation, wet treatment, or the like when the via hole is formed.

### DISCLOSURE OF THE INVENTION

An object of the present invention is to provide a miniaturized variable resistance element which is easy to manufacture and has good element performance, a manufacturing method of the variable resistance element, and an electronic device provided with the element.

According to the present invention, there are provided the below-described variable resistance element, semiconductor device, and method for manufacturing the variable resistance element.

(1) A variable resistance element including:

a first conductive portion;

an insulating film pattern provided on the first conductive portion;

a level difference with respect to an upper surface of the first conductive portion, the level difference being formed of the insulating film pattern;

a variable resistance film provided on a side surface of the level difference and having contact with the upper surface of the first conductive portion on the lower-end side of the side surface of the level difference; and

a second conductive portion having contact with the variable resistance film on the upper-end side of the side surface of the level difference.

(2) A variable resistance element including:

a first conductive portion;

an insulating film provided on the first conductive portion;

a variable resistance film provided on a side surface inside an opening penetrating through the insulating film and having contact with the first conductive portion on the lower-end side of the side surface; and

a second conductive portion having contact with the variable resistance film on the upper-end side of the side surface inside the opening.

(3) A variable resistance element including:

a first interlayer insulating film;

a first conductive portion provided on the first interlayer insulating film;

a second interlayer insulating film provided on the first conductive portion;

a variable resistance film provided on a side surface inside an opening penetrating through the second interlayer insulating film and having contact with the first conductive portion on the lower-end side of the side surface;

a buried insulating film provided so as to fill the opening; and

a second conductive portion having contact with the variable resistance film on the upper-end side of the side surface inside the opening.

(4) An electronic device including a plurality of variable resistance elements as recited in item 3 described above,

wherein the electronic device further including:
a plurality of first interconnect layers extending along a first direction, the first interconnect layers being provided on the first interlayer insulating film and covered with the second interlayer insulating film; and
a plurality of second interconnect layers extending along a second direction perpendicular to the first direction, the second interconnect layers being provided on the second interlayer insulating film; and
wherein the variable resistance film provided on the side surface inside the opening is located at respective crossover points between the first interconnect layers and the second interconnect layers, and each variable resistance element includes this variable resistance film, a first interconnect layer having contact with the variable resistance film on the lower-end side of the side surface inside the opening, and a second interconnect layer having contact with the variable resistance film on the upper-end side of the side surface inside the opening.

(5) An electronic device including:

a semiconductor substrate;

a semiconductor element provided on the semiconductor substrate; and

a variable resistance element including:
a first interlayer insulating film provided on the semiconductor substrate as to cover the semiconductor element;
a first conductive portion provided on the first interlayer insulating film and electrically connected to the semiconductor element;
a second interlayer insulating film provided on the first conductive portion;
a variable resistance film provided on a side surface inside an opening penetrating through the second interlayer insulating film and having contact with the first conductive portion on the lower-end side of the side surface;
a buried insulating film provided so as to fill the opening; and
a second conductive portion having contact with the variable resistance film on the upper-end side of the side surface inside the opening.

(6) A method for manufacturing a variable resistance element as recited in item 3 described above, including:

forming a first conductive portion on a first interlayer insulating film;

forming a second interlayer insulating film so as to cover the first conductive portion;

forming an opening reaching the first conductive portion in the second interlayer insulating film;

forming a variable resistance film;

etching back the variable resistance film to remove the variable resistance film on the second interlayer insulating film outside the opening and on the first conductive portion in the bottom of the opening, and thereby leaving the variable resistance film on the side surface inside the opening;

forming a buried insulating film so as to fill the opening; and

forming a second conductive portion having contact with the variable resistance film, on the second interlayer insulating film.

(7) The method for manufacturing a variable resistance element according to item 6 described above, including etching back and removing the first conductive portion exposed on the bottom of the opening, following the etching back of the variable resistance film.

According to the present invention, it is possible to provide a miniaturized variable resistance element which is easy to manufacture and has good element performance, a manufacturing method of the variable resistance element, and an electronic device provided with the element.

### BRIEF DESCRIPTION OF THE DRAWINGS

FIGS. 1(a) and 1(b) are a cross-sectional view and a plan view, respectively, for explaining a variable resistance element in accordance with an exemplary embodiment of the present invention;

FIGS. 2(a) and 2(b) are a cross-sectional view and a plan view, respectively, for explaining a variable resistance element in accordance with another exemplary embodiment of the present invention;

FIGS. 3(a) and 3(b) are a cross-sectional view and a plan view, respectively, for explaining a variable resistance element in accordance with another exemplary embodiment of the present invention;

FIGS. 4(a) and 4(b) are a cross-sectional view and a plan view, respectively, for explaining a variable resistance element in accordance with another exemplary embodiment of the present invention;

FIGS. 5(a) and 5(b) are a cross-sectional view and a plan view, respectively, for explaining a variable resistance element in accordance with another exemplary embodiment of the present invention;

FIGS. 6(a) and 6(b) are a cross-sectional view and a plan view, respectively, for explaining a variable resistance element in accordance with another exemplary embodiment of the present invention;

FIGS. 7(a) and 7(b) are a cross-sectional view and a plan view, respectively, for explaining a variable resistance element in accordance with another exemplary embodiment of the present invention;

FIGS. 8(a) and 8(b) are a cross-sectional view and a plan view, respectively, for explaining a variable resistance element in accordance with another exemplary embodiment of the present invention;

FIG. 9 is a cross-sectional view for explaining a method for manufacturing a variable resistance element in accordance with an exemplary embodiment of the present invention;

FIG. 10 is a plan view for explaining an electronic device in accordance with an exemplary embodiment of the present invention;

FIG. 11 is a cross-sectional view for explaining an electronic device in accordance with another exemplary embodiment of the present invention;

FIG. 12 is a cross-sectional view for explaining an electronic device in accordance with another exemplary embodiment of the present invention;

FIG. 13 is a cross-sectional view for explaining a conventional variable resistance element;

FIG. 14 is a cross-sectional view for explaining another conventional variable resistance element; and

FIG. 15 is a cross-sectional view for explaining another conventional variable resistance element.

### BEST MODE FOR CARRYING OUT THE INVENTION

A variable resistance element according to the present invention includes: a first conductive portion; an insulating film pattern provided on this first conductive portion; a level difference with respect to the upper surface of the first conductive portion, the level difference being formed of this insulating film pattern; a variable resistance film provided on a side surface of this level difference and having contact with the upper surface of the first conductive portion on the lower-end side of the side surface of the level difference; and a second conductive portion having contact with the variable resistance film on the upper-end side of the side surface of the level difference.

In this variable resistance element, an opening reaching the first conductive portion can be formed in an insulating film provided on the first conductive portion, thereby utilizing a side surface inside the opening as the side surface of the level difference formed of the insulating film pattern. As this opening, it is possible to form a via hole, the opening shape of which in plan view is circular, square or rectangular, or a linear trench. A space inside this opening can be formed of a cylindrical column or a rectangular solid.

Use of a structure, in which the variable resistance film formed on the side surface of the level difference is brought into contact with one conductive portion on the lower-end side of the side surface of the level difference and with the other conductive portion on the upper-end side of the level difference, makes it easy to form an element smaller than the minimum processing dimension of lithography. Thus, it is possible to fabricate a variable resistance element having a high on/off ratio.

The variable resistance film in the present invention is preferably a film made of a transition metal oxide, such as a titanium oxide or a nickel oxide, and particularly preferably a film made of a nickel oxide. The first conductive portion and the second conductive portion in the present invention are preferably made of a material selected from the group consisting of tungsten, titanium, tantalum, a nitride of tungsten, titanium or tantalum, ruthenium, a ruthenium oxide, platinum, copper, and aluminum. The first and second conductive portions are particularly preferably made of any one of these materials if the variable resistance film is made of a nickel oxide.

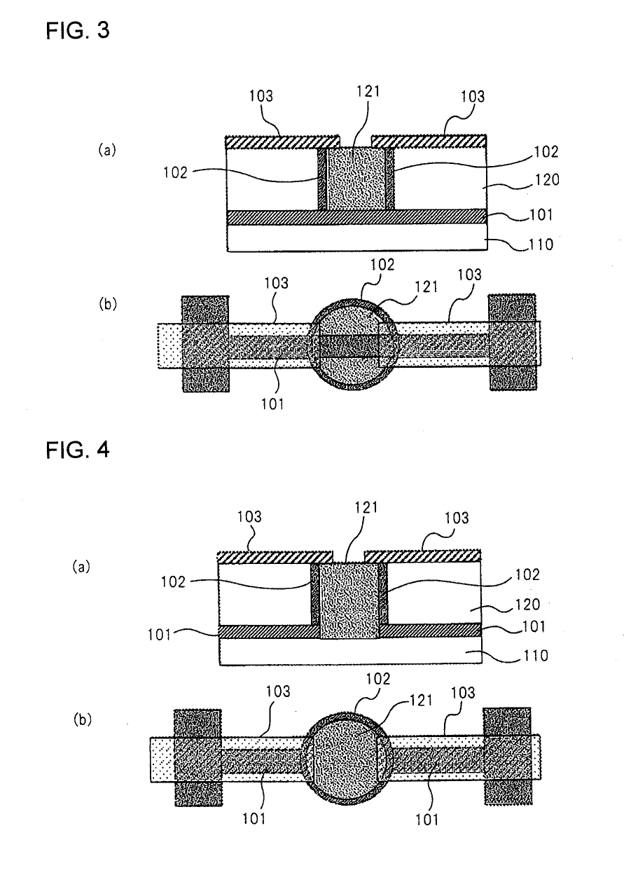

In the variable resistance element according to the present invention, the resistance of the variable resistance film can be varied by applying a voltage pulse between the first conductive portion and the second conductive portion. According to the present invention, it is possible to form a plurality of variable resistance elements for a variable resistance film formed inside a single opening. Thus, the present invention is advantageous to the large-scale integration of variable resistance elements. For example, by bringing two or more conductive portions into contact with a variable resistance film formed on a side surface inside a single opening on the lower-end side of the side surface as one electrode and/or by bringing two or more conductive portions into contact with the variable resistance film on the upper-end side of the side surface as the other electrode, it is possible to configure a variable resistance element for each pair of upper-end side and lower-end side conductive portions. Thus, the large-scale integration of elements becomes possible. In cases where, for example, a plurality of upper-end side conductive portions are formed (for example, the structure illustrated in FIG. 3 to be described later) for a single lower-end side conductive portion through a common variable resistance film, it is possible to form variable resistance elements corresponding in number to the number of upper-end side conductive portions. Alternatively, in cases where a plurality of upper-end side conductive portions are formed (for example, the structure illustrated in FIG. 4 to be described later) for a plurality of lower-end side conductive portions through a common variable resistance film, it is possible to form variable resistance elements corresponding in number to the number of upper-end side or lower-end side conductive portions. Here, the variable resistance film may be formed continuously between a pair of lower-end side and upper-end side electrode portions. Thus, it is possible to configure a plurality of variable resistance elements by taking advantage of a single continuous variable resistance film.

In the variable resistance element according to the present invention, it is possible to create a high-resistance state and a low-resistance state and maintain these states, even if power is turned off, by applying an electrical pulse between a first conductive portion and a second conductive portion. According to the present invention, it is possible to provide a variable resistance element which is small in occupation area and nonvolatile. Such an element is extremely beneficial as a switching element for a programmable semiconductor integrated circuit. The variable resistance element according to the present invention is also beneficial for use as an information storage element for memories.

As described above, according to the present invention, it is possible to form a variable resistance element smaller than the minimum processing dimension in a lithography technique. Thus, it is possible to obtain a sufficiently high on/off ratio. In addition, since the variable resistance element can be miniaturized and densified, large-scale high integration becomes easy to achieve. According further to the present invention, an interelement switching variation is suppressed since it is possible to reduce a space in which a conduction path of the variable resistance element is formed. Thus, it is possible to form a high-reliability variable resistance element.

Hereinafter, exemplary embodiments will be described using the accompanying drawings.

### Element Structure Example 1

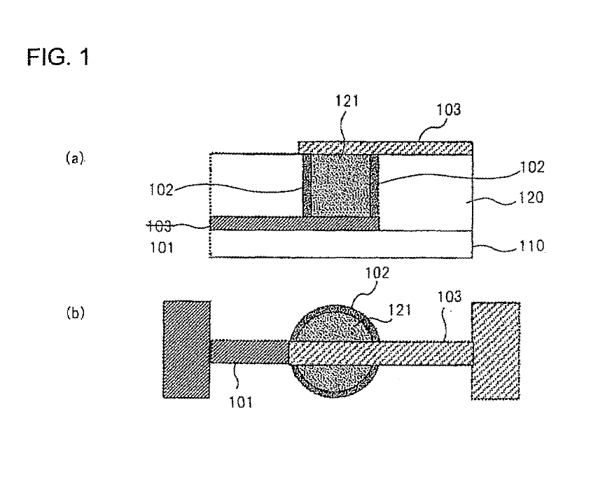

A first element structure example of the present invention is illustrated in the cross-sectional view of FIG. 1(a) and in the plan view of FIG. 1(b). FIG. 1(a) illustrates a cross section viewed along the center line of a lower electrode 101 and an upper electrode 103 in the longitudinal direction thereof in FIG. 1(b), whereas FIG. 1(b) perspectively illustrates the element structure with respect to a second interlayer insulating film 120, in order to show a layout of element components.

In this element structure, the lower electrode 101 is formed on a first interlayer insulating film 110, the second interlayer insulating film 120 is formed so as to cover this lower electrode, a variable resistance film 102 is provided on a side surface inside a via hole formed in this second interlayer insulating film and in contact with the lower electrode in the bottom of the via hole, a buried insulating film 121 is provided inside this via hole, and the upper electrode 103 is formed on this buried insulating film and the second interlayer insulating film and in contact with the variable resistance film 102. The lower electrode and the upper electrode are led out for interconnection.

Here, the first interlayer insulating film, the second interlayer insulating film and the buried insulating film can be formed of a silicon dioxide film. The lower electrode and the upper electrode can be formed of a material selected from the group consisting of tungsten, titanium, tantalum, a nitride of tungsten, titanium or tantalum, ruthenium, a ruthenium oxide, platinum, copper and aluminum. The variable resistance film can be formed of a transition metal oxide, such as a titanium oxide or a nickel oxide.

According to such an element structure as described above, an element area can be determined by the line width of the upper electrode or the lower electrode and by the thickness of the variable resistance film. In the related art, the minimum dimension is determined by the capacity of lithography used to form the upper electrode. In contrast, in the variable resistance element according to the present invention, it is possible to reduce the cross-sectional area (area of a cross section perpendicular to a conduction path direction) of the variable resistance film by controlling the thickness of the variable resistance film of the element. Thus, it is possible to reduce the element area.

### Element Structure Example 2

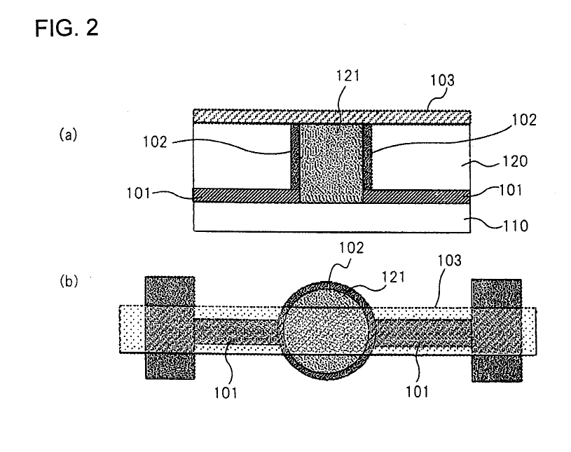

A second element structure example of the present invention is illustrated in the cross-sectional view of FIG. 2(a) and in the plan view of FIG. 2(b). FIG. 2(a) illustrates a cross section viewed along the center line of a lower electrode 101 and an upper electrode 103 in the longitudinal direction thereof in FIG. 2(b), whereas FIG. 2(b) perspectively illustrates the element structure with respect to the upper electrode 103 and a second interlayer insulating film 120, in order to show a layout of element components.

In this element structure, as in element structure example 1 described above, the variable resistance film 102 is provided on a side surface inside a via hole formed in the second interlayer insulating film 120, and a buried insulating film 121 is provided inside the via hole. However, these element structures differ in the lower electrode 101 and the upper electrode 103. The rest of configuration except these electrodes is the same as that of element structure example 1. The lower electrode 101 is provided separately on both the right-hand side and the left-hand side of the via hole and has contact with the variable resistance film 102 on the lower-end side of the side surface inside the via hole. The upper electrode 103 integrally extends in the horizontal direction of the via hole and has contact with the variable resistance film 102 on the upper-end side of the side surface inside the via hole. In this structural example, two variable resistance elements are formed for each one via hole.

### Element Structure Example 3

A third element structure example of the present invention is illustrated in the cross-sectional view of FIG. 3(a) and in the plan view of FIG. 3(b). FIG. 3(a) illustrates a cross section viewed along the center line of a lower electrode 101 and an upper electrode 103 in the longitudinal direction thereof in FIG. 3(b), whereas FIG. 3(b) perspectively illustrates the element structure with respect to the upper electrode 103, a second interlayer insulating film 120 and a buried insulating film 121, in order to show a layout of element components.

In this element structure, as in element structure example 1 described above, the variable resistance film 102 is provided on a side surface inside a via hole formed in the second interlayer insulating film 120, and a buried insulating film 121 is provided inside the via hole. However, these element structures differ in the lower electrode 101 and the upper electrode 103. The rest of configuration except these electrodes is the same as that of element structure example 1. The lower electrode 101 integrally extends in the horizontal direction under the via hole and has contact with the variable resistance film 102 on the lower-end side of the side surface inside the via hole. The upper electrode 101 is provided separately on both the right-hand side and the left-hand side of the via hole and has contact with the variable resistance film 102 on the upper-end side of the side surface inside the via hole. In this structural example, two variable resistance elements are formed for each one via hole.

### Element Structure Example 4

A fourth element structure example of the present invention is illustrated in the cross-sectional view of FIG. 4(a) and in the plan view of FIG. 4(b). FIG. 4(a) illustrates a cross section viewed along the center line of a lower electrode 101 and an upper electrode 103 in the longitudinal direction thereof in FIG. 4(b), whereas FIG. 4(b) perspectively illustrates the element structure with respect to the upper electrode 103 and a second interlayer insulating film 120, in order to show a layout of element components.

In this element structure, as in element structure example 1 described above, the variable resistance film 102 is provided on a side surface inside a via hole formed in the second interlayer insulating film 120, and a buried insulating film 121 is provided inside the via hole. However, these element structures differ in the lower electrode 101 and the upper electrode 103. The rest of configuration except these electrodes is the same as that of element structure example 1. The lower electrode 101 is provided separately on both the right-hand side and the left-hand side of the via hole and has contact with the variable resistance film 102 on the lower-end side of the side surface inside the via hole. The upper electrode 103 is provided separately on both the right-hand side and the left-hand side of the via hole and has contact with the variable resistance film 102 on the upper-end side of the side surface inside the via hole. In this structural example, two variable resistance elements are formed for each one via hole.

### Element Structure Example 5

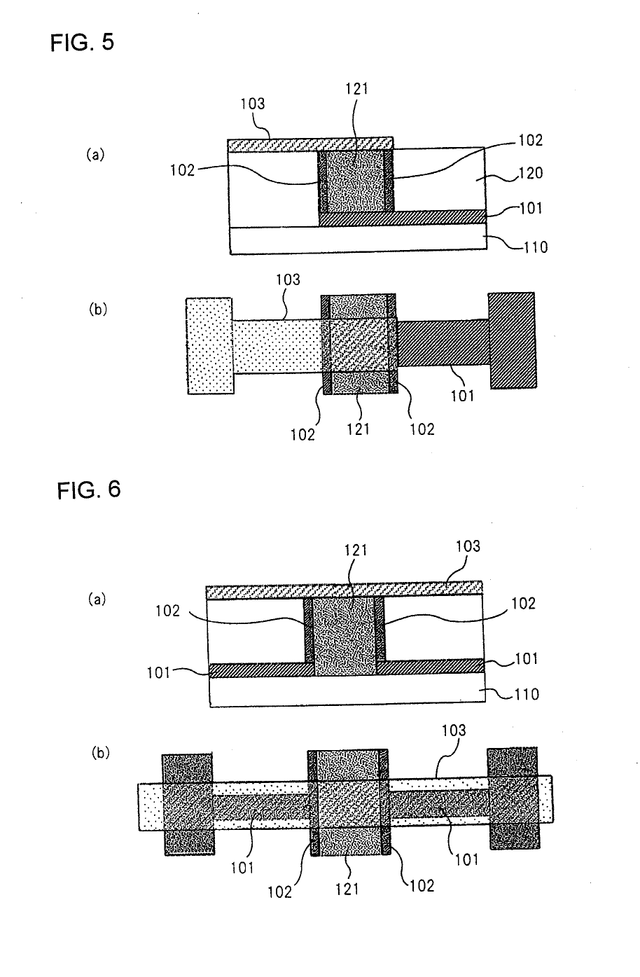

A fifth element structure example of the present invention is illustrated in the cross-sectional view of FIG. 5(a) and in the plan view of FIG. 5(b). FIG. 5(a) illustrates a cross section viewed along the center line of a lower electrode 101 and an upper electrode 103 in the longitudinal direction thereof in FIG. 5(b), whereas FIG. 5(b) perspectively illustrates the element structure with respect to the upper electrode 103 and a second interlayer insulating film 120, in order to show a layout of element components.

This element structure is the same as element structure example 1 except that a trench is provided in place of the via hole formed in the second interlayer insulating film 120 in element structure example 1 described above, a variable resistance film 102 is provided on a side surface inside this trench, and a buried insulating film 121 is provided inside this trench.

### Element Structure Example 6

A sixth element structure example of the present invention is illustrated in the cross-sectional view of FIG. 6(a) and in the plan view of FIG. 6(b). FIG. 6(a) illustrates a cross section viewed along the center line of a lower electrode 101 and an upper electrode 103 in the longitudinal direction thereof in FIG. 6(b), whereas FIG. 6(b) perspectively illustrates the element structure with respect to the upper electrode 103 and a second interlayer insulating film 120, in order to show a layout of element components.

In this element structure, as in element structure example 5 described above, the variable resistance film 102 is provided on a side surface inside a trench formed in the second interlayer insulating film 120, and a buried insulating film 121 is provided inside the trench. However, these element structures differ in the lower electrode 101 and the upper electrode 103. The rest of configuration except these electrodes is the same as that of element structure example 5. The lower electrode 101 is provided separately on both the right-hand side and the left-hand side of the trench and has contact with the variable resistance film 102 on the lower-end side of the side surface inside the trench. The upper electrode 103 integrally extends in the horizontal direction over the trench, so as to traverse the trench, and has contact with the variable resistance film 102 on the upper-end side of the side surface inside the trench. In this structural example, two variable resistance elements are formed for each one trench.

### Element Structure Example 7

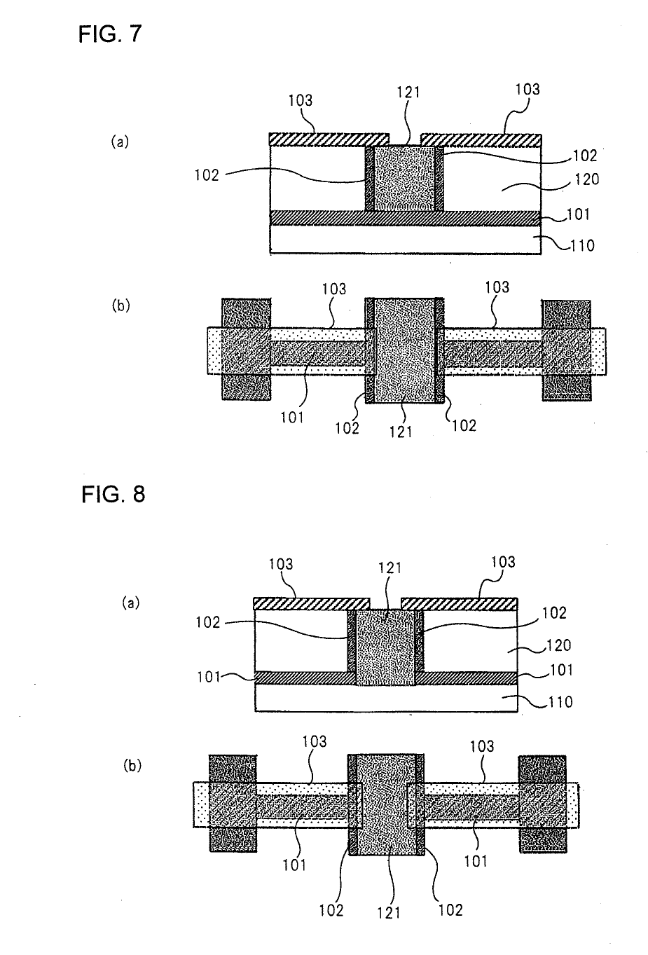

A seventh element structure example of the present invention is illustrated in the cross-sectional view of FIG. 7(a) and in the plan view of FIG. 7(b). FIG. 7(a) illustrates a cross section viewed along the center line of a lower electrode 101 and an upper electrode 103 in the longitudinal direction thereof in FIG. 7(b), whereas FIG. 7(b) perspectively illustrates the element structure with respect to the upper electrode 103 and a second interlayer insulating film 120, in order to show a layout of element components.

In this element structure, as in element structure example 5 described above, the variable resistance film 102 is provided on a side surface inside a trench formed in the second interlayer insulating film 120, and a buried insulating film 121 is provided inside the trench. However, these element structures differ in the lower electrode 101 and the upper electrode 103. The rest of configuration except these electrodes is the same as that of element structure example 5. The lower electrode 101 integrally extends in the horizontal direction under the trench, so as to traverse the trench, and has contact with the variable resistance film 102 on the lower-end side of the side surface inside the trench. The upper electrode 103 is provided separately on both the right-hand side and the left-hand side of the trench and has contact with the variable resistance film 102 on the upper-end side of the side surface inside the trench. In this structural example, two variable resistance elements are formed for each one trench.

### Element Structure Example 8

An eighth element structure example of the present invention is illustrated in the cross-sectional view of FIG. 8(a) and in the plan view of FIG. 8(b). FIG. 8(a) illustrates a cross section viewed along the center line of a lower electrode 101 and an upper electrode 103 in the longitudinal direction thereof in FIG. 8(b), whereas FIG. 8(b) perspectively illustrates the element structure with respect to the upper electrode 103 and a second interlayer insulating film 120, in order to show a layout of element components.

In this element structure, as in element structure example 5 described above, the variable resistance film 102 is provided on a side surface inside a trench formed in the second interlayer insulating film 120, and a buried insulating film 121 is provided inside the trench. However, these element structures differ in the lower electrode 101 and the upper electrode 103. The rest of configuration except these electrodes is the same as that of element structure example 5. The lower electrode 101 is provided separately on both the right-hand side and the left-hand side of the trench and has contact with the variable resistance film 102 on the lower-end side of the side surface inside the trench. The upper electrode 103 is provided separately on both the right-hand side and the left-hand side of the trench and has contact with the variable resistance film 102 on the upper-end side of the side surface inside the trench. In this structural example, two variable resistance elements are formed for each one trench.

### Manufacturing Examples

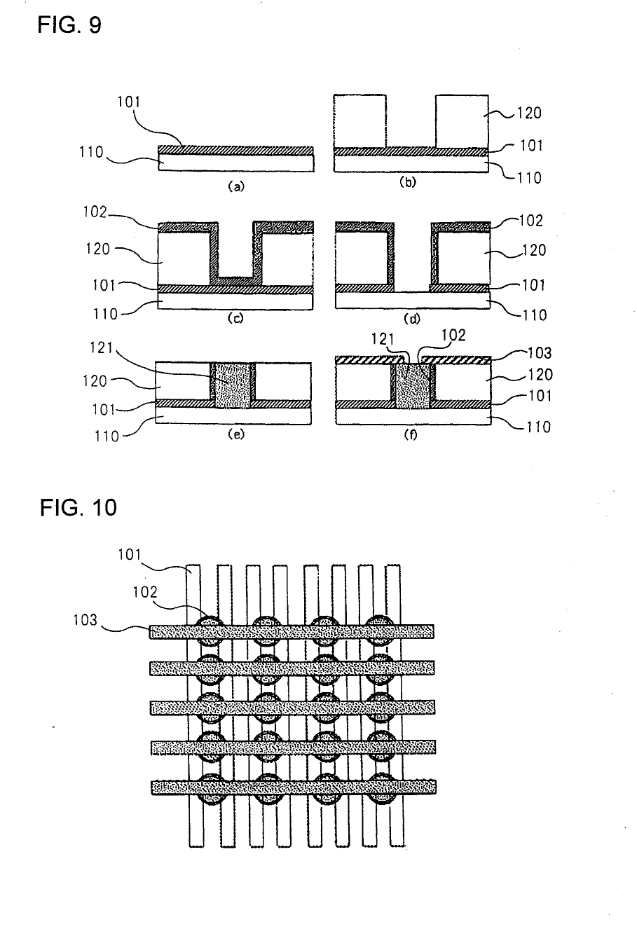

Hereinafter, an example of manufacturing element structure example 4 will be cited to describe a manufacturing method of the present invention using FIGS. 9(a) to 9(f).

As illustrated in FIG. 9(a), an insulator thin film, such as a silicon dioxide film, is formed on a semiconductor substrate (not illustrated) as a first interlayer insulating film 110, using a CVD method or a coating method. The thickness of the insulator thin film, which is dependent on the thickness of an element as a whole, can be adjusted within the range of, for example, 200 nm to 800 nm. Subsequently, a conductive film 101 for a lower electrode is formed. As this conductive film 101, it is possible to use a laminated film (shown as a single-layer film in the figure) in which for example, a titanium nitride film or a tantalum nitride film is formed to a thickness of several tens of nanometers, and then a film of platinum group metal, such as Pt or Ru, is formed on the film to a thickness of 1 to 200 nm. The conductive film 101 for a lower electrode is previously processed into a predetermined shape using a lithography technique and a dry etching technique or the like.

Next, as illustrated in FIG. 9(b), an insulator thin film, such as a silicon dioxide film, is formed as a second interlayer insulating film 120 in the same way as the first interlayer insulating film, using a CVD method or a coating method. The thickness of the insulator thin film can be adjusted within the range of, for example, 10 nm to 500 nm. Subsequently, a via hole is formed in the second interlayer insulating film using a lithography technique and a dry etching technique. At this time, dry etching performed when the via hole is formed is stopped on the conductive film 101 for a lower electrode.

Note here that in this manufacturing example, although an explanation will be made of a case in which a via hole is formed as an opening, a trench may be formed in place of the via hole.

Next, as illustrated in FIG. 9(c), a variable resistance film 102 is formed over the entire surface of the second interlayer insulating film in which the via hole is formed. At that time, the variable resistance film is allowed to form along an inner wall (side surface) of the via hole. As the variable resistance film, it is possible to use, for example, a nickel oxide or a titanium oxide. The thickness of the variable resistance film is adjusted so that the variable resistance film is deposited on a sidewall inside the via hole to a thickness ranging from several nanometers to 100 nm. As a formation method, it is possible to use a sputtering method or a CVD method.

Next, the entire surface of the variable resistance film 102 is etched back by anisotropic dry etching. The etching back may be stopped at a point in time when the conductive film 101 for a lower electrode is exposed. Subsequently, the conductive film 101 in the bottom of the exposed via hole is removed also by dry etching. With these steps, there is obtained the shape illustrated in FIG. 9(d). What is important for the shape of the conductive film 101 for a lower electrode is that the shape is designed so that the width thereof (length in a direction perpendicular to the longitudinal direction of the shape) is smaller than the opening diameter of the via hole after the formation of the variable resistance film. Since such a shape as described above has been realized at the time of the above-described processing of the conductive film 101, lower electrodes separated from each other are formed on one and the other sides of the via hole, respectively, by the above-described dry etching of the conductive film 101.

Next, as illustrated in FIG. 9(e), an insulating film 121 is formed so as to fill the via hole in which the variable resistance film 102 is formed on a side surface thereof. As this filling insulating film, it is possible to use the same material as that of the first and second interlayer insulating films. Subsequently, the insulating film and the variable resistance film adhering to portions other than the via hole are removed using a chemical-mechanical polishing (CMP) method.

Next, as illustrated in FIG. 9(f), a conductive film 103 for an upper electrode is formed so as to have contact with the upper end of the variable resistance film formed on the side surface inside the via hole. As this conductive film 103, it is possible to use, for example, a laminated film in which a film of platinum group metal, such as Pt or Ru, is formed to a thickness of 1 to 200 nm, and then a titanium nitride film or tantalum nitride film is formed on the metal film to a thickness of several tens of nanometers. Subsequently, the conductive film 103 is subjected to patterning into a predetermined shape using a lithography technique and a dry etching technique.

By applying a voltage pulse to the variable resistance element formed using such a manufacturing method as described above, it is possible to vary the resistance of the variable resistance film provided along the side surface inside the via hole.

In this manufacturing example, a lower electrode can also be formed by etching back and, therefore, an element region can be formed in a self-aligned manner. Thus, it is easy to ensure alignment margins. In addition, it is possible to form two lower electrodes, thereby obtaining two variable resistance elements, for each one of conductive films for a lower electrode formed in a previous step. Note that if the conductive film for a lower electrode in the bottom of the via hole is not etched back and removed, it is possible to obtain element structure example 3 illustrated in FIG. 3. In addition, by selecting the presence or absence of this etching back step for forming the lower electrode and designing the patterning of the upper electrodes as appropriate, it is possible to obtain the variable resistance elements shown in element structure examples 1 to 4 (FIGS. 1 to 4).

Since the size of a variable resistance element available in this manufacturing example can be determined by the line width of an electrode and the thickness of the variable resistance film, it is possible to reduce the occupation area of an element. In the case of a variable resistance film made of a transition metal oxide such as a nickel oxide, there is formed a filamentary conductive path (conduction path) having an extremely small area (area of a cross section perpendicular to a direction of conduction) is formed within the film. The variable resistance element goes into a conducting state (ON state) due to the formation of this conduction path. Accordingly, it is possible to obtain sufficiently low ON resistance even if an element area (area of contact between the electrode and the variable resistance film) is reduced. On the other hand, an OFF-state resistance value has area dependency. Consequently, it is possible to attain a high on/off ratio if the element area is reduced. In addition, the conduction path is formed in such a manner that an insulating film is dielectrically broken down. Accordingly, it can be expected that if the element area reduces, then a variation in the formation of the conduction path also reduces. That is, it is possible to suppress a variation in the performance of the element as a switch.

Hereinafter, an explanation will be made of a structure of a device provided with a variable resistance element according to the present invention.

### Device Structure Example 1

FIG. 10 illustrates a structural example of a device provided with variable resistance elements according to the present invention as switch elements. The variable resistance elements in the figure are illustrated perspectively with respect to an interlayer insulating film.

A plurality of signal lines X (103) extending along a direction X and a plurality of signal line Y (101) extending along a direction Y perpendicular to the direction X are formed with the interlayer insulating film therebetween. A variable resistance film 102 provided on a side surface inside a via hole formed in the interlayer insulating film is located at each crossover point of a signal line X and a signal line Y. The via hole is filled with an insulating film. This variable resistance film 102, the signal line Y (lower electrode 101) having contact with the variable resistance film on the lower-end side of a side surface inside the via hole, and the signal line X (upper electrode 103) having contact with the variable resistance film on the upper-end side of the side surface inside the via hole constitute one variable resistance element. A plurality of such variable resistance elements are disposed in matrix arrangement. In this structural example, two adjacent signal lines Y have contact with a variable resistance film provided inside one via hole, thereby forming two variable resistance elements using the respective signal lines Y as lower electrodes. In addition, these two variable resistance elements share one signal line X as their upper electrodes.

By selecting a variable resistance element at a desired crossover point and placing the variable resistance element in an ON state, a signal line X and a signal line Y associated with the variable resistance element placed in an ON state are caused to connect to each other at low resistance. Switching can thus be carried out.

Note that in this structural example, a plurality of via holes are formed along the direction Y to form elements. Alternatively, trenches may be formed along the direction Y in place of the plurality of via holes disposed along the direction Y. Then, variable resistance films may be provided on side surfaces inside these trenches, thereby forming elements. Buried insulating films are provided inside these trenches. A plurality of signal lines X extending along the direction X are arranged so as to traverse these trenches, and thus a plurality of variable resistance elements are formed along the direction Y for each one trench. This means that a row of a plurality of variable resistance elements extending along the direction Y share a variable resistance film provided on a side surface inside one trench. At this time, a signal line Y (lower electrode) extending in the same direction as the longitudinal direction of the trench is subjected to patterning and arranged, so as to be able to have contact with the variable resistance film provided on the side surface inside the trench.

### Device Structure Example 2

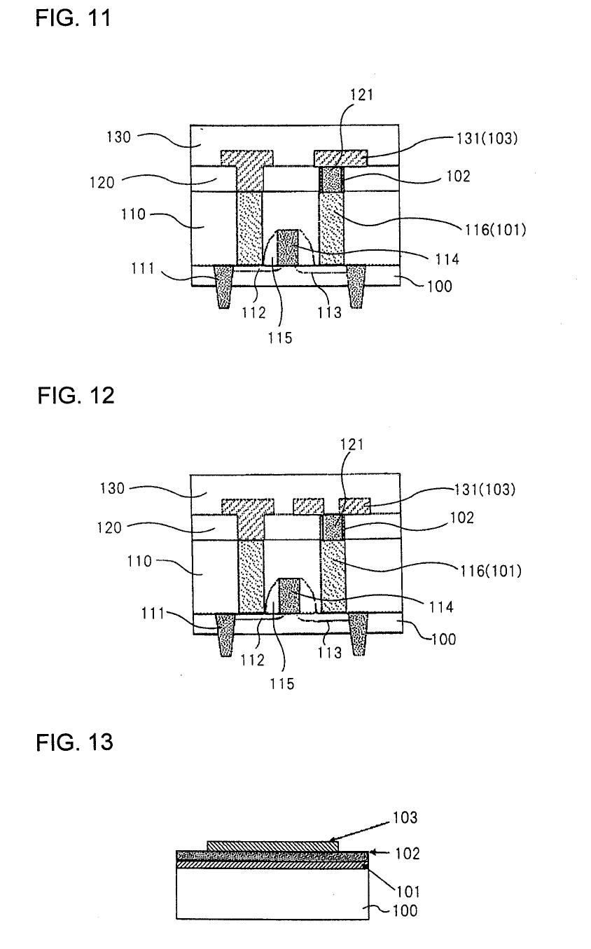

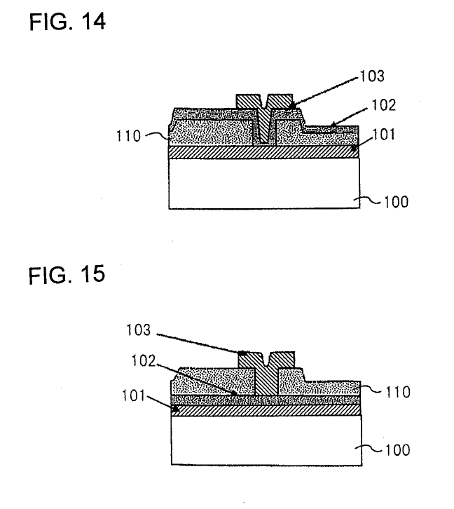

FIG. 11 illustrates a structural example of a device provided with a variable resistance element according to the present invention as a memory element.

An element isolator 111 is provided in a semiconductor substrate 100, and a field-effect transistor including a source region 112, a drain region 113, a gate oxide film (not illustrated) and a gate electrode 114 is provided on an active region surrounded by the element isolator. A sidewall insulating film 115 is provided on both sides of the gate electrode.

Contact holes are formed in a first interlayer insulating film 110. A conductive material is buried in these contact holes to form contact plugs 116. The contact plugs 116 are connected to the source region 112 and the drain region 113, respectively.

A via hole is formed in a second interlayer insulating film 120. A variable resistance film 102 is provided on the inner side surface of the via hole, and an insulating film 121 is filled in the via hole. This variable resistance film 102 is connected to a contact plug 116 the lower end of which is connected to the drain region 113, and the upper end of the variable resistance film 102 is connected to an upper-layer bit line 131. Here, the variable resistance film 102, the contact plug 116 (lower electrode 101) in contact with the lower end of this variable resistance film, and a bit line 131 (upper electrode 103) in contact with the upper end of this variable resistance film constitute a variable resistance element. The structure of this variable resistance element corresponds to element structure example 1 described above (FIG. 1 (a)).

The contact plug connected to the source region 112 is connected to an upper-layer interconnect by way of a via plug penetrating through the second interlayer insulating film 120. A third interlayer insulating film 130 is provided on the second interlayer insulating film 120.

By placing the variable resistance element in an ON state or an OFF state, it is possible to store a signal “1” or “0” even if power is turned off.

### Device Structure Example 3

FIG. 12 illustrates a modified example of device structure example 2 described above. This device structure example 3 is the same as device structure example 2 described above except plate lines 131 constituting the upper electrode of a variable resistance element.

Two plate lines are arranged in contact with a variable resistance film provided on a side surface inside one via hole. Thus, there are formed two variable resistance elements associated with these plate lines. This element structure corresponds to element structure example 3 (FIG. 3(a)) described above.

In this device structure example 3, it is possible to retain four pieces of information by a combination of the ON and OFF storage states of the two variable resistance elements.

As has been described heretofore, according to the present invention, there is obtained a variable resistance element having a sufficiently high on/off ratio. Furthermore, since elements can be easily miniaturized and densified, it is possible to form a large-scale highly-integrated device. Still furthermore, since a region in which a conduction path of a variable resistance element is formed can be reduced, it is possible to suppress an interelement variation in switching performance. Thus, it is possible to form a high-reliability variable resistance element.

The application of the present invention is not limited to the content described in the specification. For example, the present invention can be used in combination with at least one of a logic circuit or a memory circuit provided with semiconductor elements.

The present invention is characterized mainly in that a side surface of a level difference with respect to a substrate plane is utilized at the time of detecting a resistance change as an ON/OFF state. Accordingly, the present invention is applicable to variable resistance elements using various variable resistance materials, as far as this effect is available. For example, the present invention is also applicable to a variable resistance element utilizing a phase-change material made of chalcogenide, to a variable resistance element using a perovskite-type variable resistance material, such as a perovskite-type oxide, and to a variable resistance element using a variable resistance material made of organic matter.

In the exemplary embodiments, an explanation has been made of examples in which a side surface inside a via hole or a trench is utilized. As another example, however, a variable resistance film may be formed on a side surface of a convexly formed insulating film pattern, and such a variable resistance film may be utilized for a variable resistance element.

Having thus described the present invention with reference to the exemplary embodiments, the present invention is not limited to the above-described exemplary embodiments. Various modifications understandable to those skilled in the art may be made to the constitution and details of the present invention within the scope thereof.

This application claims the benefit of priority based on Japanese Patent Application No. 2007-84569, filed on Mar. 28, 2007, the entire content of which is incorporated herein by reference.

1. A variable resistance element comprising:
a first conductive portion;
an insulating film pattern provided on the first conductive portion;
a level difference with respect to an upper surface of the first conductive portion, the level difference being formed of the insulating film pattern;
a variable resistance film provided on a side surface of the level difference and having contact with the upper surface of the first conductive portion on the lower-end side of the side surface of the level difference; and
a second conductive portion having contact with the variable resistance film on the upper-end side of the side surface of the level difference.

2. A variable resistance element comprising:
a first conductive portion;
an insulating film provided on the first conductive portion;
a variable resistance film provided on a side surface inside an opening penetrating through the insulating film and having contact with the first conductive portion on the lower-end side of the side surface; and
a second conductive portion having contact with the variable resistance film on the upper-end side of the side surface inside the opening.

3. A variable resistance element comprising:
a first interlayer insulating film;
a first conductive portion provided on the first interlayer insulating film;
a second interlayer insulating film provided on the first conductive portion;
a variable resistance film provided on a side surface inside an opening penetrating through the second interlayer insulating film and having contact with the first conductive portion on the lower-end side of the side surface;
a buried insulating provided so as to fill the opening; and
a second conductive portion having contact with the variable resistance film on the upper-end side of the side surface inside the opening.

4. The variable resistance element according to claim 2 or 3, wherein the opening is a via hole or a trench.

5. The variable resistance element according to claim 1, wherein the resistance of the variable resistance film is varied by applying a voltage pulse between the first conductive portion and the second conductive portion.

6. The variable resistance element according to claim 1, wherein more than one first conductive portion has contact with the variable resistance film.

7. The variable resistance element according to claim 1, wherein more than one second conductive portion has contact with the variable resistance film.

8. The variable resistance element according to claim 1, wherein the variable resistance film is made of a transition metal oxide.

9. The variable resistance element according to claim 8, wherein the variable resistance film is made of a nickel oxide.

10. The variable resistance element according to claim 1, wherein the first conductive portion and the second conductive portion each are made of a material selected from the group consisting of tungsten, titanium, tantalum, a nitride of tungsten, titanium or tantalum, ruthenium, a ruthenium oxide, platinum, copper, and aluminum.

11. An electronic device comprising a plurality of variable resistance elements as recited in claim 3, wherein the electronic device comprises:
a plurality of first interconnect layers extending along a first direction, the first interconnect layers being provided on the first interlayer insulating film and covered with the second interlayer insulating film; and
a plurality of second interconnect layers extending along a second direction perpendicular to the first direction, the second interconnect layers being provided on the second interlayer insulating film; and
wherein the variable resistance film provided on the side surface inside the opening is located at respective crossover points between the first interconnect layers and the second interconnect layers, and each variable resistance element includes the variable resistance film, a first interconnect layer having contact with the variable resistance film on the lower-end side of the side surface inside the opening, and a second interconnect layer having contact with the variable resistance film on the upper-end side of the side surface inside the opening.

12. An electronic device comprising:
a semiconductor substrate;
a semiconductor element provided on the semiconductor substrate;
a first interlayer insulating film provided on the semiconductor substrate so as to cover the semiconductor element;
a second interlayer insulating film provided on the first interlayer insulating film; and
a variable resistance element including:
a first conductive portion electrically connected to the semiconductor element;
an opening Penetrating through the second interlayer insulating film;
a variable resistance film provided on a side surface inside the opening and having contact with the first conductive portion on the lower-end side of the side surface;
a buried insulating film provided so as to fill the opening; and
a second conductive portion having contact with the variable resistance film on the upper-end side of the side surface inside the opening.

13. A method for manufacturing a variable resistance element as recited in claim 3, comprising:
forming a first conductive portion on a first interlayer insulating film;
forming a second interlayer insulating film so as to cover the first conductive portion;
forming an opening reaching the first conductive portion in the second interlayer insulating film;
forming a variable resistance film;
etching back the variable resistance film to remove the variable resistance film on the second interlayer insulating film outside the opening and on the first conductive portion in the bottom of the opening, and thereby leaving the variable resistance film on the side surface inside the opening;
forming a buried insulating film so as to fill the opening; and
forming a second conductive portion having contact with the variable resistance film, on the second interlayer insulating film.

14. The method for manufacturing a variable resistance element according to claim 13, further comprising etching back and removing the first conductive portion exposed on the bottom of the opening, following the etching back of the variable resistance film.
